(19) United States
(12) Patent Application Publication
(10) Pub. No.: US 2014/0353676 A1
(43) Pub. Date: Dec. 4, 2014

(54) LIGHT EMITTING CHIP

(71) Applicant: DISCO CORPORATION, Tokyo (JP)

(72) Inventors: Takashi Okamura, Tokyo (JP); Minoru Suzuki, Tokyo (JP)

(73) Assignee: DISCO CORPORATION, Tokyo (JP)

(21) Appl. No.: 14/290,265

(22) Filed: May 29, 2014

(30) Foreign Application Priority Data
May 31, 2013 (JP) 2013-114869

(51) Int. Cl. H01L 33/48

(52) U.S. Cl. CPC H01L 33/48
USPC 257/76

(57) ABSTRACT

A light emitting chip includes a device chip having a light emitting layer on a front surface side and a transparent member bonded to a back surface side of the device chip. The transparent member is transmissive to light emitted from the light emitting layer. The transparent member is formed into a frustum shape having a first surface, a second surface that has a smaller area than the first surface, and an inclined sidewall that connects the first surface and the second surface.

### BACKGROUND OF THE INVENTION

1. Field of the Invention

The present invention relates to a light emitting chip including a device chip in which a light emitting layer is formed.

2. Description of the Related Art

Light emitting devices including light emitting diode (LED), laser diode (LD), and so forth have been put into practical use. These light emitting devices normally include a light emitting chip having a device chip in which a light emitting layer that emits light by application of a voltage is formed. In manufacturing of this device chip, first an epitaxial layer (crystal layer) is grown as the light emitting layer in the respective regions partitioned by planned dividing lines in a lattice manner on a substrate for crystal growth. Thereafter, the substrate for crystal growth is divided along the planned dividing lines to be turned to individual pieces. Therefore, the device chips for individual light emitting chips are formed.

In the light emitting chip, in a device chip in which the light emitting layer that emits green or blue light is an InGaN-based material layer, generally sapphire is used as the substrate for crystal growth and an n-type GaN semiconductor layer, an InGaN light emitting layer, and a p-type GaN semiconductor layer are sequentially epitaxially grown over this sapphire substrate. Furthermore, an external lead-out electrode is formed for each of the n-type GaN semiconductor layer and the p-type GaN semiconductor layer.

A light emitting diode is formed by fixing a back surface side (sapphire substrate side) of this device chip to a lead frame serving as a base pedestal and covering a front surface side (light emitting layer side) of the device chip by a lens member. For such a light emitting diode, enhancement in the luminance is considered as an important challenge and various methods for enhancing the light extraction efficiency have been proposed before (refer to e.g. Japanese Patent Laid-Open No. Hei 4-10670).

### SUMMARY OF THE INVENTION

Light generated in the light emitting layer by application of a voltage is emitted mainly from two major surfaces (front surface and back surface) of a layer stack including the light emitting layer. For example, the light emitted from the front surface of the layer stack (major surface on a lens member side) is extracted to an external of the light emitting diode via the lens member and so forth. Meanwhile, the light emitted from the back surface of the layer stack (major surface on a sapphire substrate side) travels in the sapphire substrate and part thereof is reflected at an interface between the sapphire substrate and the lead frame and so forth to return to the layer stack.

For example, if a thin sapphire substrate is used for the device chip for the purpose of enhancement in the processability in cutting and so forth, a distance between the back surface of the layer stack and the interface between the sapphire substrate and the lead frame is short. In this case, a ratio of light reflected at the interface between the sapphire substrate and the lead frame to return to the layer stack is higher than that when the sapphire substrate is thick or when a transparent member with a rectangular parallelepiped shape is disposed between the sapphire substrate and the lead frame. The layer stack absorbs light. Therefore, if the ratio of light that returns to the layer stack is higher as above, a light extraction efficiency of the light emitting diode is lower.

Therefore, an object of the present invention is to provide a light emitting chip having a new configuration that allows enhancement in the light extraction efficiency.

In accordance with an aspect of the present invention, there is provided a light emitting chip including a device chip having a light emitting layer on the front surface side and a transparent member formed into a frustum shape having a first surface, a second surface that has a smaller area than the first surface, and an inclined sidewall that connects the first surface and the second surface. The back surface side of the device chip is bonded to the first surface of the transparent member by a transparent resin.

In accordance with another aspect of the present invention, there is provided a light emitting chip including a device chip having a light emitting layer on the front surface side and a transparent member formed into a frustum shape having a first surface, a second surface that has a smaller area than the first surface, and an inclined sidewall that connects the first surface and the second surface. The back surface side of the device chip is bonded to the second surface of the transparent member by a transparent resin.

According to this configuration, because the light emitting chip has the transparent member formed into the frustum shape on the back surface side of the device chip including the light emitting layer, an incident angle of light traveling in the transparent member to the inclined sidewall can be changed according to the angle of the inclined sidewall. This can eliminate the case in which the light traveling in the transparent member is totally reflected at the inclined sidewall and can increase a ratio of light that goes out of the transparent member. In addition, it is also possible to set the traveling direction of the light reflected at the inclined sidewall in such a manner that the ratio of light that goes out of the transparent member is made high. Due to this, the ratio of light that returns to the light emitting layer due to reflection can be suppressed to a low ratio and the light extraction efficiency can be enhanced.

Preferably, the device chip is formed by stacking the light emitting layer formed of a GaN semiconductor layer over a sapphire substrate. According to this configuration, the light extraction efficiency can be enhanced in a light emitting chip that emits blue or green light. Furthermore, even when the sapphire substrate is made thin, reflected light can be made incident on a position out of the light emitting layer according to the thickness of the transparent member. Thus, a thin sapphire substrate can be used without lowering the light extraction efficiency and high processability attributed to a thin substrate for crystal growth can be kept.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view schematically showing a configuration example of a light emitting diode according to a first embodiment;

FIG. 2 is a schematic sectional view showing how light is emitted in the light emitting diode according to the first embodiment;

FIG. 3 is a schematic sectional view showing how light is emitted in a light emitting diode according to a comparative example;

FIG. 4 is a schematic sectional view showing how light is emitted in a light emitting diode according to a second embodiment;

FIG. 5A is a perspective view schematically showing a configuration example of a light emitting diode according to a third embodiment;

FIG. 5B is a schematic sectional view of the light emitting diode according to the third embodiment; and

FIG. 6 is a graph showing a measurement result of a luminance.

### DETAILED DESCRIPTION OF THE PREFERRED EMBODIMENTS

### First Embodiment

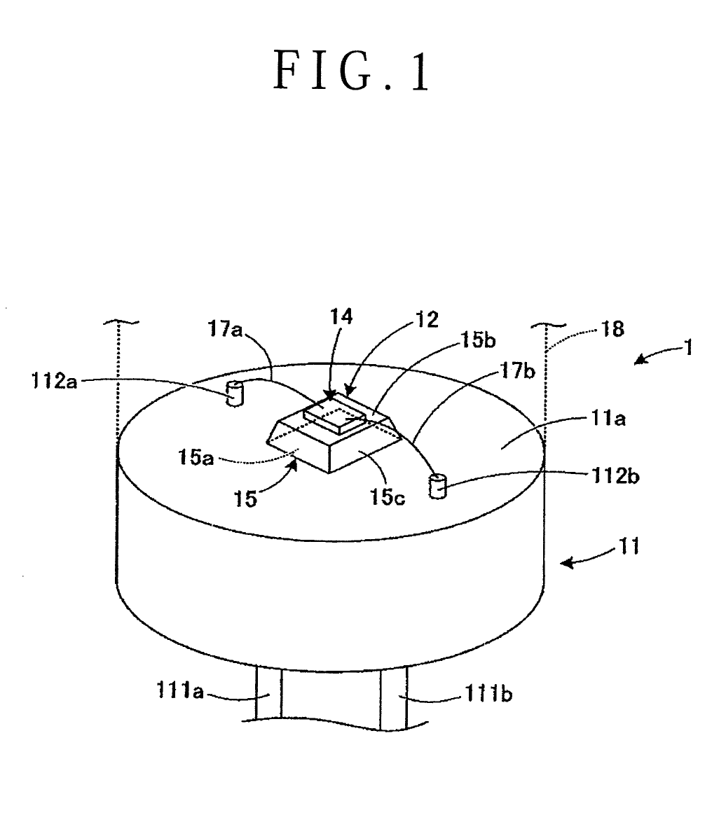

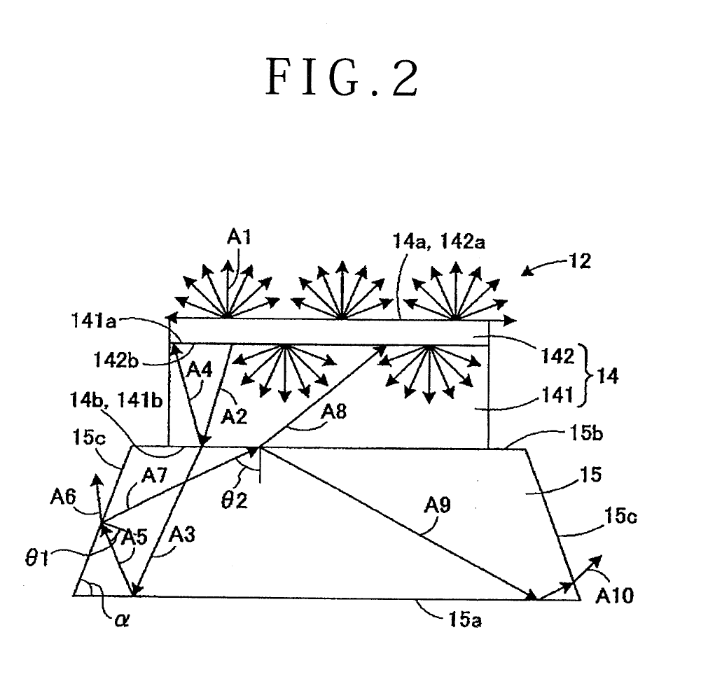

Embodiments of the present invention will be described below with reference to the accompanying drawings. FIG. 1 is a perspective view schematically showing a configuration example of a light emitting diode according to a first embodiment. FIG. 2 is a schematic sectional view showing how light is emitted from a light emitting chip of the light emitting diode according to the first embodiment. As shown in FIG. 1, a light emitting diode 1 includes a lead frame 11 serving as a base pedestal and a light emitting chip 12 supported and fixed by the lead frame 11.

The lead frame 11 is formed into a circular column shape by a material such as a metal and two lead members 111a and 111b having electrical conductivity are provided on a side of the back surface equivalent to one major surface. The lead members 111a and 111b are insulated from each other and function as the anode and cathode, respectively, of the light emitting diode 1. The lead members 111a and 111b are connected to an external power supply (not shown) via wiring (not shown) or the like.

On a front surface 11a equivalent to an other major surface of the lead frame 11, two connection terminals 112a and 112b insulated from each other are disposed at a predetermined interval. The connection terminal 112a is connected to the lead member 111a inside the lead frame 11. The connection terminal 112b is connected to the lead member 111b inside the lead frame 11. Therefore, potentials of the connection terminals 112a and 112b are equivalent to potentials of the lead members 111a and 111b, respectively.

A light emitting chip 12 is disposed on the front surface 11a of the lead frame 11 and between the connection terminal 112a and the connection terminal 112b. As shown in FIG. 2, the light emitting chip 12 has a device chip 14 and a transparent member 15 disposed on a side of a back surface 14b of this device chip 14. The device chip 14 includes a sapphire substrate 141 having a rectangular shape as its planar shape and a layer stack 142 provided on a front surface 141a of the sapphire substrate 141. The layer stack 142 includes plural semiconductor layers formed by using GaN-based semiconductor materials (GaN semiconductor layers).

The layer stack 142 is formed by sequentially epitaxially growing an n-type semiconductor layer (e.g. n-type GaN layer), in which electrons are the majority carriers, a semiconductor layer (e.g. InGaN layer) to serve as a light emitting layer, and a p-type semiconductor layer (e.g. p-type GaN layer), in which holes are the majority carriers. Furthermore, on the sapphire substrate 141, two electrodes (not shown) that are connected to the n-type semiconductor layer and the p-type semiconductor layer, respectively, and apply a voltage to the layer stack 142 are formed. These electrodes may be included in the layer stack 142.

The transparent member 15 is formed of glass (e.g. soda glass or borosilicate glass), resin, etc. and is formed by a material through which light emitted from the light emitting layer is transmitted. The transparent member 15 is formed into a truncated four-sided pyramid shape as shown in FIG. 1 and a first surface 15a as its back surface and a second surface 15b as its front surface are each formed into a rectangular shape in plan view. The second surface 15b has a smaller area than the first surface 15a. Each of the sides of the first surface 15a is connected to a respective one of the sides of the second surface 15b by an inclined sidewall 15c. Each inclined sidewall 15c is formed into a trapezoidal shape. It is preferable for the transparent member 15 to have a thickness equivalent to or larger than that of the sapphire substrate 141.

The first surface 15a of the transparent member 15 is bonded to the front surface 11a of the lead frame 11 by a resin (not shown) having translucency. Furthermore, the second surface 15b of the transparent member 15 is bonded to the whole of a back surface 141b of the sapphire substrate 141 (i.e. the back surface 14b of the device chip 14) by a resin (not shown) having translucency.

The two connection terminals 112a and 112b provided on the lead frame 11 are connected to the two electrodes of the light emitting chip 12 via lead wires 17a and 17b, respectively, having electrical conductivity. Due to this, the voltage of the power supply connected to the lead members 111a and 111b is applied to the layer stack 142. When the voltage is applied to the layer stack 142, electrons flow from the n-type semiconductor layer into the semiconductor layer serving as the light emitting layer and holes flow from the p-type semiconductor layer into it. As a result, the recombination of the electrons and the holes occurs in the semiconductor layer serving as the light emitting layer and light having a predetermined wavelength is emitted. In the present embodiment, because the semiconductor layer serving as the light emitting layer is formed by using a GaN-based semiconductor material, blue or green light corresponding to the band gap of the GaN-based semiconductor material is emitted.

A dome-shaped lens member 18 covering a side of a front surface 14a of the device chip 14 is attached to a circumferential edge of the side of the front surface 11a of the lead frame 11. The lens member 18 is formed of a material, such as a resin, having a predetermined refractive index and refracts the light emitted from the layer stack 142 of the device chip 14 to guide the light to the external of the light emitting diode 1 along predetermined directions. In this manner, the light emitted from the device chip 14 is extracted to the external of the light emitting diode 1 via the lens member 18.

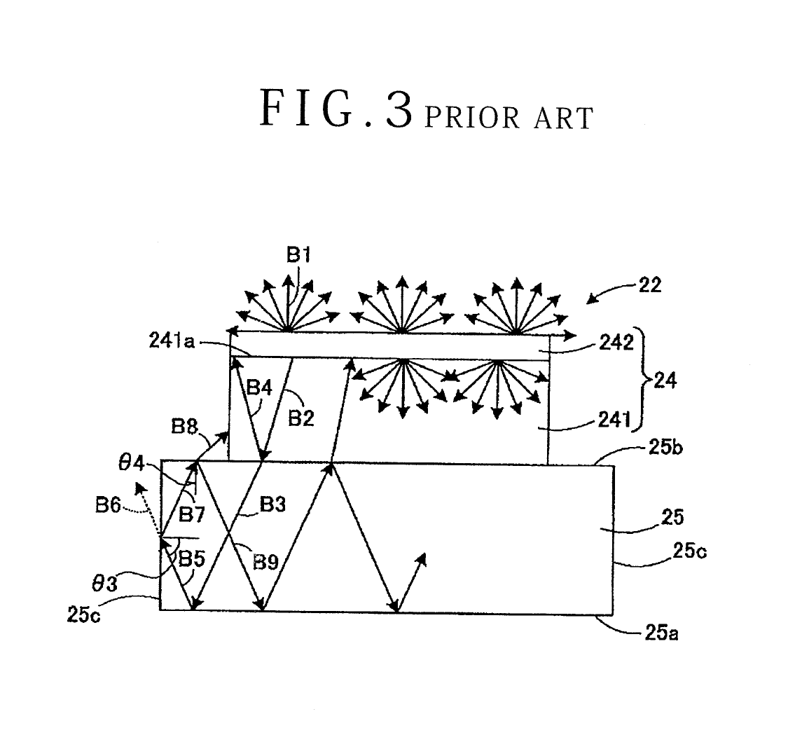

Next, description will be made about a luminance improvement effect by the light emitting diode 1 according to the first embodiment with reference to a light emitting diode according to a comparative example. FIG. 3 is a schematic sectional view showing how light is emitted from a light emitting chip of the light emitting diode according to the comparative example. As shown in FIG. 3, the light emitting diode according to the comparative example has a configuration in common with the light emitting diode 1 according to the first embodiment except for the following points. Specifically, a transparent member 25 is formed into a rectangular parallelepiped shape. In addition, its first and second surfaces 25a and 25b are so made as to have the same area and a side surface 25c is oriented parallel to the vertical direction. That is, in a light emitting chip 22 according to the comparative example, a device chip 24 including a sapphire substrate 241 having a rectangular shape as its planar shape and a layer stack 242 provided on a front surface 241a of the sapphire substrate 241 is bonded to the transparent member 25.

As shown in FIG. 2, in the light emitting diode 1 according to the first embodiment (see FIG. 1), light generated in the semiconductor layer serving as the light emitting layer is emitted mainly from a front surface 142a of the layer stack 142 (i.e. the front surface 14a of the device chip 14) and a back surface 142b. The light emitted from the front surface 142a of the layer stack 142 (e.g. optical path A1) is extracted to the external of the light emitting diode 1 via the lens member 18 (see FIG. 1) and so forth as described above. On the other hand, e.g. light emitted from the back surface 142b of the layer stack 142 to travel on an optical path A2 is incident on the back surface 14b of the device chip 14, which is an interface between the sapphire substrate 141 and the transparent member 15, so that part thereof is transmitted to the transparent member 15 side (optical path A3) and the other part is reflected (optical path A4). The light reflected to travel on the optical path A4 is incident on the layer stack 142 and absorbed, and thus cannot be extracted to the external. The light transmitted to the transparent member 15 side to travel on the optical path A3 is incident on the first surface 15a and reflected by the front surface 11a (see FIG. 1) of the lead frame 11 (optical path A5).

The light traveling on the optical path A5 is incident on an interface between the inclined sidewall 15c of the transparent member 15 and an air layer at an incident angle θ1, so that part thereof is transmitted to the air layer side and emitted out (optical path A6) and the other part is reflected (optical path A7). The light reflected to travel on the optical path A7 is incident on the second surface 15b of the transparent member 15 at an incident angle θ2, so that part thereof is transmitted to the sapphire substrate 141 and absorbed by the layer stack 142 (optical path A8) and the other part is reflected (optical path A9). The light traveling on the optical path A9 is incident on the first surface 15a and reflected by the front surface 11a (see FIG. 1) of the lead frame 11. Then, the reflected light is incident on the inclined sidewall 15c and path thereof is emitted out to the air layer (optical path A10).

In contrast, as shown in FIG. 3, although optical paths B1 to B5 of the light emitting chip 22 according to the comparative example are similar to the optical paths A1 to A5 of the light emitting chip 12 according to the first embodiment, the optical path B5 in the comparative example is incident on the side surface 25c of the transparent member 25 whereas the optical path A5 in the first embodiment is incident on the inclined sidewall 15c. The optical path B5 in the comparative example is incident on an interface between the side surface 25c and the air layer at an incident angle θ3, so that part of the light is transmitted to the air layer and emitted out (optical path B6) and the other part is reflected (optical path B7). The incident angle θ3 is larger than the incident angle θ1 in the first embodiment. Therefore, an amount of light traveling on the optical path B6 is smaller than an amount of light traveling on the optical path A6. Depending on the condition, the light is totally reflected at the side surface 25c without being emitted out from the side surface 25c.

The light reflected to travel on the optical path B7 is incident on the second surface 25b of the transparent member 25 at an incident angle 94, so that part thereof is emitted out to the air layer side (optical path B8) and the other part is reflected (optical path B9). A direction of the light traveling on the optical path B8 is oriented toward the layer stack 242 via the sapphire substrate 241 and most part thereof is absorbed by the layer stack 242. Furthermore, the incident angle θ4 is different from and smaller than the incident angle θ2 in the first embodiment. Thus, an amount of light traveling on the optical path B9 in the comparative example is smaller than an amount of light traveling on the optical path A9 in the embodiment. Therefore, an amount of light emitted out to the air layer side after traveling on the optical path B9 and then being reflected by the first surface 25a and the second surface 25b of the transparent member 25 is smaller than an amount of light traveling on the optical path A10 in the first embodiment.

As described above, according to the light emitting diode 1 in accordance with the first embodiment, a larger amount of light can be emitted out through the optical path A6 compared with the optical path B6 in the comparative example because the inclined sidewall 15c is formed in the transparent member 15. Furthermore, in the comparative example, light is emitted out through the optical path B8 but most part thereof is absorbed by the layer stack 242 and the amount of light traveling on the optical path B9 and the subsequent optical paths is also small. In contrast, in the first embodiment, it is also possible to increase the amount of light emitted out through the optical path A10 after passing through the optical paths A7 and A9. Due to this, in the first embodiment, the ratio of light that returns to the layer stack 142 can be suppressed to a low ratio and the ratio of light that goes out of the transparent member 15 can be made high. Thus, the light extraction efficiency can be enhanced and improvement in the luminance can be achieved.

The sapphire substrate is hard and not easy to process and therefore it is preferable to use a thin sapphire substrate to enhance the processability. In the light emitting diode 1 according to the first embodiment, the light extraction efficiency can be kept high by the transparent member 15 even when the thickness of the sapphire substrate 141 is reduced. That is, there is no need to increase the thickness of the sapphire substrate 141 for keeping the light extraction efficiency to sacrifice the processability.

Second and third embodiments different from the first embodiment will be described below. In the second and third embodiments, constituent elements in common with the first embodiment are given the same symbols and description thereof is omitted.

### Second Embodiment

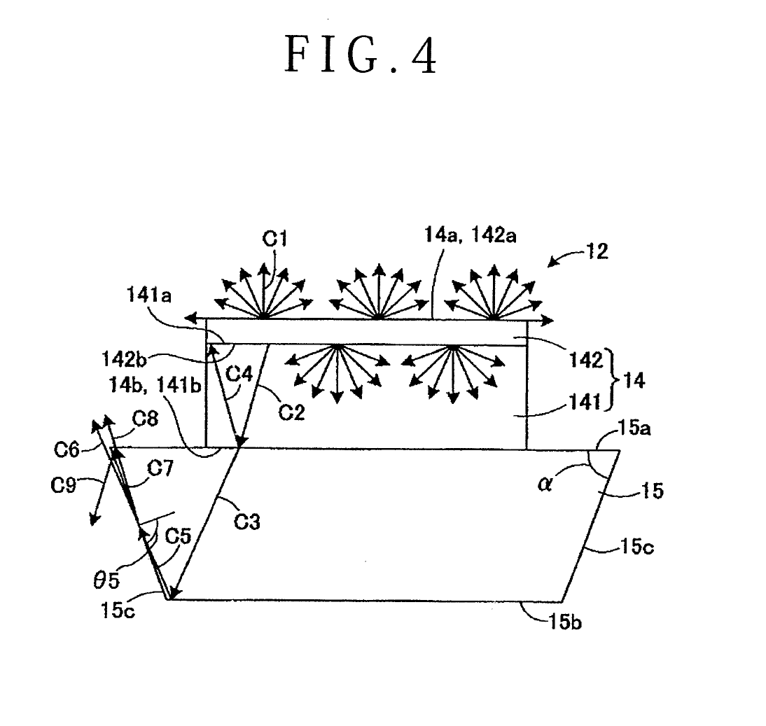

FIG. 4 is a schematic sectional view showing how light is emitted from a light emitting chip of a light emitting diode according to a second embodiment. The light emitting diode according to the second embodiment is different from the first embodiment only in that the shape of the transparent member 15 is so changed as to be vertically inverted. Specifically, in the transparent member 15 of the second embodiment, the first surface 15a serves as the front surface (upper surface) and is bonded to the while of the back surface 141b of the sapphire substrate 141 (i.e. the back surface 14b of the device chip 14) by a resin (not shown) having translucency. Furthermore, the second surface 15b serves as the back surface (lower surface) and is bonded to the front surface 11a (see FIG. 1) of the lead frame 11 by a resin (not shown) having translucency.

Next, description will be made about a luminance improvement effect by the light emitting diode 1 according to the second embodiment with reference to the above-described comparative example. Although optical paths C1 to C5 of the light emitting diode 1 according to the second embodiment are similar to the optical paths B1 to B5 of the light emitting diode according to the comparative example, the optical path C5 in the second embodiment is incident on the inclined sidewall 15c at an incident angle θ5, so that part of the light is transmitted to the air layer side and emitted out (optical path C6) and the other part is reflected (optical path C7). The incident angle θ5 is larger than the incident angle θ3 in the comparative example. Therefore, a larger amount of light travels on the optical path C7 compared with the optical path C6. The light traveling on this optical path C7 is incident on the first surface 15a of the transparent member 15, so that part thereof is transmitted to the air layer side and emitted out (optical path C8) and the other part is also transmitted to the air layer side and emitted out after being reflected (optical path C9). That is, the light traveling on the optical path C5 travels on the optical paths C6 to C9 and is emitted out to the air layer side at a high ratio.

Therefore, also by the light emitting diode 1 according to the second embodiment, the ratio of light that returns to the layer stack 142 can be suppressed to a low ratio and improvement in the luminance can be achieved compared with the comparative example.

### Third Embodiment

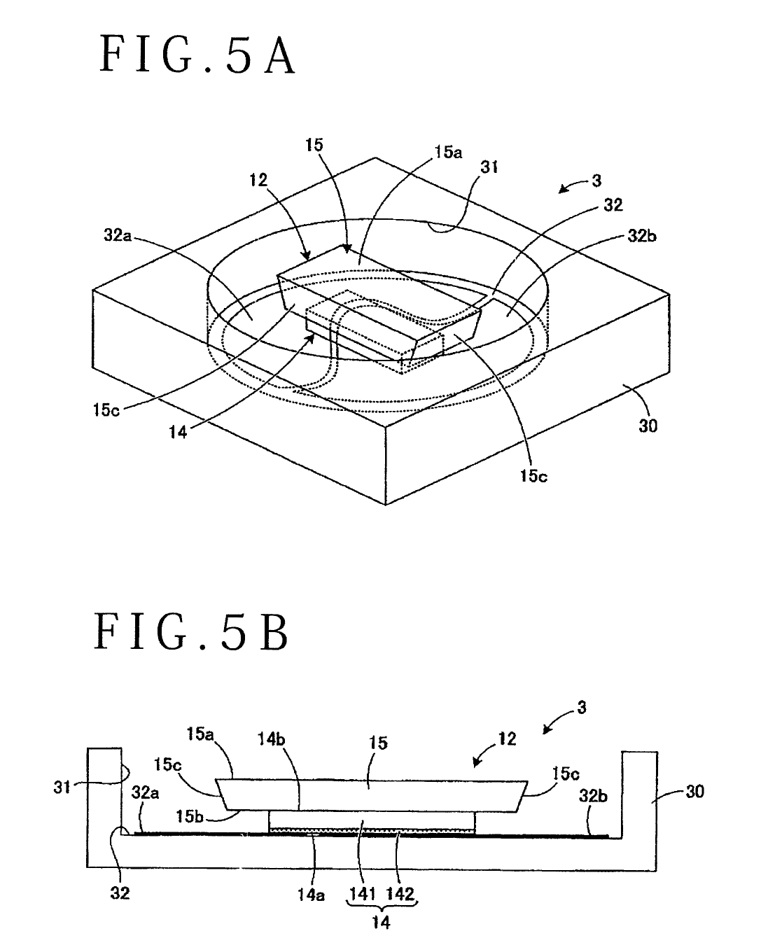

FIG. 5A is a perspective view schematically showing a configuration example of a light emitting diode according to a third embodiment and FIG. 5B is a schematic sectional view of the light emitting diode according to the third embodiment. As shown in FIGS. 5A and 5B, a light emitting diode 3 according to the third embodiment is obtained by supporting and fixing the light emitting chip 12 on a mounting surface 32 formed at a bottom surface in a recess 31 of a package 30. On the mounting surface 32, two connection electrodes 32a and 32b insulated from each other are disposed at a predetermined interval.

The light emitting chip 12 of the third embodiment includes the device chip 14 and the transparent member 15 similarly to the light emitting chip 12 of the first embodiment and is so fixed that its vertical direction is inverted from the first embodiment. Electrodes (not shown) provided on the front surface 14a of the device chip 14 in the third embodiment are formed by protrusion-shaped terminals called bumps. They are connected to the connection terminals 32a and 32b through supporting and fixing of the front surface 14a of the device chip 14 on the mounting surface 32, so that the light emitting chip 12 is mounted by flip-device chip mounting.

Next, an experiment carried out in order to check the luminance improvement effect of the light emitting diodes according to the above-described embodiments will be described. In this experiment, four kinds of light emitting diodes 1 (working examples 1 to 4) that have a configuration similar to that of the light emitting diode 1 according to the first embodiment or the second embodiment and are made different from each other in the shape of the transparent member 15 and a light emitting diode (comparative example) given a shape of the transparent member 25 similar to the comparative example were fabricated.

The light emitting chips 12 and 22 (see FIGS. 2 to 4) having the same specifications were used in all of working examples 1 to 4 and comparative example. Specifically, as the light emitting chips 12 and 22, light emitting chips were used that were each obtained by forming the layer stack 142 or 242 including a light emitting layer formed of a GaN semiconductor layer on the sapphire substrate 141 or 241 having an area (vertical×horizontal) of 0.595 mm×0.270 mm as the area of the front surface and back surface and a thickness (height) of 0.10 mm. Bonding between the sapphire substrate 141 or 241 and the transparent member 15 or 25 was made by using an adhesive made of a resin having sufficiently low absorbance.

For each of the light emitting chips 12 and 22 used in working examples 1 to 4 and comparative example, glass with a thickness of 0.10 to 0.15 mm was used as the transparent member 15 or 25. The transparent member 15 used in working example 1 was formed into a shape similar to that of the transparent member 15 of the second embodiment and the transparent member 15 used in working examples 2 to 4 was formed into a shape similar to that of the transparent member 15 of the first embodiment. An area (vertical×horizontal) of the first surface 15a of the transparent member 15 in working examples 1 to 4 was set to 0.8 mm×0.8 mm and an area of the first and second surfaces 25a and 25b in the transparent member 25 of the comparative example was also set to 0.8 mm×0.8 mm. An angle α formed by the first surface 15a and the inclined sidewall 15c of the transparent member 15 (hereinafter, referred to simply as the angle α) in working examples 1 and 2 was set to 60°. An angle α in working example 3 was set to 30° and an angle α in working example 4 was set to 45°.

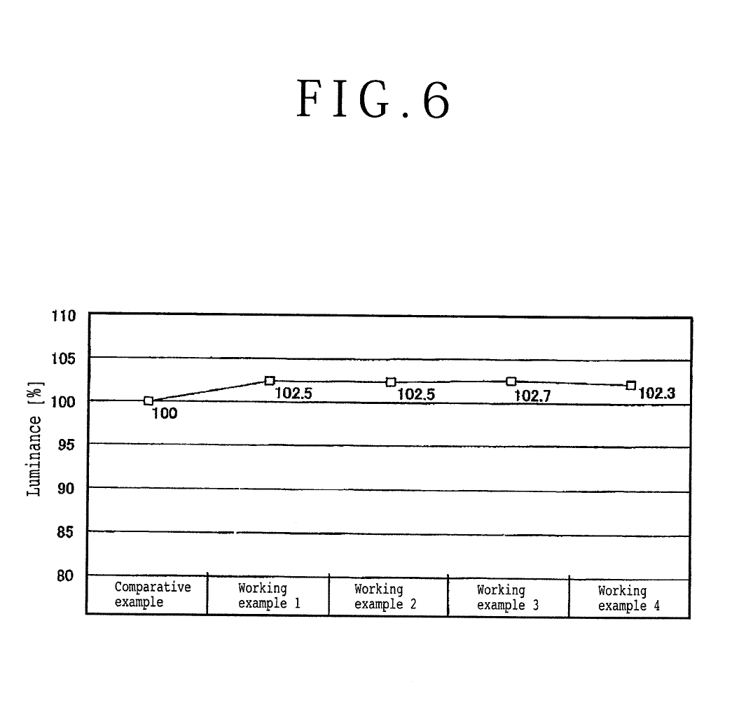

In this experiment, a total value of an intensity (power) of all light radiated from each light emitting diode 1 was measured (total radiant flux measurement) and converted into a luminance calculated with the comparative example, in which the transparent member 25 was formed into a rectangular parallelepiped shape, regarded as the criterion (100%). FIG. 6 is a graph showing the measurement result. In FIG. 6, an ordinate indicates the luminance (%). In working examples 1 to 4, the luminance is higher by about 2 to 3% than the comparative example and the light extraction efficiency can be enhanced.

The present invention is not limited to the above-described embodiments and can be carried out with various changes. The sizes, shapes, and so forth of constituent elements in the above-described embodiments are not limited to those represented in the accompanying drawings and can be arbitrarily changed within such a range as to exert effects of the present invention. Besides, the present invention can be carried out with arbitrary changes without departing from the scope of the object of the present invention.

For example, in the above-described embodiments, the device chip 14 using a sapphire substrate and a GaN-based semiconductor material is exemplified. However, the substrate for crystal growth and the semiconductor material are not limited to the embodiments. For example, a GaN substrate may be used as the substrate for crystal growth. Although it is preferable to reduce the thickness of the substrate for crystal growth, such as a sapphire substrate, to enhance the processability, the substrate for crystal growth does not necessarily need to be thin.

Furthermore, although the layer stack 142 in which an n-type semiconductor layer, a semiconductor layer that emits light, and a p-type semiconductor layer are sequentially provided is exemplified in the above-described embodiments, the configuration of the layer stack 142 is not limited thereto. It is enough for the layer stack 142 to be so configured as to be capable of at least emission of light through the recombination of electrons and holes. Moreover, it is enough for the shape of the transparent member 15 to be a frustum shape. Besides a truncated four-sided pyramid shape, it may be a truncated cone shape, a truncated elliptic cone shape, or a truncated n-sided pyramid shape (n is a natural number equal to or larger than three).

In addition, the device chip 14 may be a device chip that emits infrared light (AlGaAs, GaAsP, or the like). In this case, the same effects as those of the above-described embodiments are obtained by forming the transparent member 15 by a material transmissive to infrared light. Moreover, the same effects as those of the above-described embodiments are obtained also when the device chip 14 emits ultraviolet light and the transparent member 15 is formed by a material transmissive to ultraviolet light.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A light emitting chip comprising:
a device chip having a light emitting layer on a front surface side; and
a transparent member formed into a frustum shape having a first surface, a second surface that has a smaller area than the first surface, and an inclined sidewall that connects the first surface and the second surface,
wherein a back surface side of the device chip is bonded to the first surface of the transparent member by a transparent resin.

2. The light emitting chip according to claim 1, wherein the device chip is formed by stacking the light emitting layer formed of a GaN semiconductor layer over a sapphire substrate.

3. A light emitting chip comprising:
a device chip having a light emitting layer on a front surface side; and
a transparent member formed into a frustum shape having a first surface, a second surface that has a smaller area than the first surface, and an inclined sidewall that connects the first surface and the second surface,
wherein a back surface side of the device chip is bonded to the second surface of the transparent member by a transparent resin.

4. The light emitting chip according to claim 3, wherein the device chip is formed by stacking the light emitting layer formed of a GaN semiconductor layer over a sapphire substrate.
